(19) United States
(12) Patent Application Publication
(10) Pub. No.: US 2026/0020251 A1
(43) Pub. Date: Jan. 15, 2026

(54) High-Density Ferroelectric Memory, and Manufacturing Method Therefor and Application Thereof

(71) Applicants: BEIJING SUPERSTRING ACADEMY OF MEMORY TECHNOLOGY, Beijing (CN); PEKING UNIVERSITY, Beijing (CN)

(72) Inventors: Qianqian HUANG, Beijing (CN); Zhiyuan FU, Beijing (CN); Ru HUANG, Beijing (CN)

(21) Appl. No.: 18/996,706

(22) PCT Filed: Nov. 9, 2023
(86) PCT No.: PCT/CN2023/130698

§ 371 Date: Jan. 17, 2025

(30) Foreign Application Priority Data
Mar. 14, 2023 (CN) 202310242051.4

(51) Int. Cl. H10B 63/00

(52) U.S. Cl. CPC H10B 63/82

(57) ABSTRACT

A high-density ferroelectric memory, and a preparation method therefor and an application thereof, belonging to the field of semiconductor memories. In the memory, multiple memory cells are arranged in an array, and the two sides of the array of the memory cells are connected to substantially orthogonal word lines and bit lines, the memory cell of the present invention adopts a stacked structure of a top electrode, a resistive switching dielectric layer, an intermediate metal layer, a ferroelectric dielectric layer, and a bottom electrode, which is electrically equivalent to a ferroelectric capacitor and a resistive switching selector connected in series; the voltage division of the distributed ferroelectric capacitor in the unselected cells is reduced by regulating the RC delay of the memory cell, so that its disturbance is reduced; and the capacitance value of the ferroelectric capacitor is stable, and the influence of the disturbance voltage can be effectively reduced by RC regulation. The storage window of the memory is improved and the bit error rate is reduced, without increasing additional area overhead.

### FIELD OF THE INVENTION

The present invention relates to the field of semiconductor memories, and in particular to a high-density ferroelectric memory.

### BACKGROUND OF THE INVENTION

With the continuous advancement of electronic information technology, the demand for low-power consumption and high-capacity memory is constantly increasing. Traditional flash memory (Flash) utilizes the principle of charge storage and adopts the erasing/programming method of hot electron injection and FN tunneling, which results in relatively high power consumption and relatively long erasing/programming time; while traditional dynamic random access memory (DRAM) has a relatively short memory retention time due to transistor leakage, and requires high-frequency refresh, which brings a relatively high dynamic power consumption. Nowadays, with the continuous development of intelligent Internet of Things, artificial intelligence and big data, these problems will become increasingly serious.

Ferroelectric dielectric materials, due to their asymmetric lattice structure, overall exhibit spontaneous polarization charges that can be controlled by an electric field, and the polarization reversal speed depends on the lattice relaxation time, thus memories designed based on ferroelectric materials have the advantages of low power consumption and high speed. However, traditional ferroelectric materials based on perovskite structures (such as PZT, BTO, etc.) have low compatibility with CMOS processes due to their complex composition; and the size effect is obvious, making it impossible to integrate in advanced process nodes, resulting in memories based on traditional ferroelectric materials only playing a role in some special edge applications.

In recent years, researchers have found that CMOS-compatible hafnium oxide (HfO₂) films can induce ferroelectricity under specific doping, stress and annealing conditions, breaking the constraints of difficult integration and poor miniaturization of ferroelectric material devices. Among different types of hafnium oxide-based ferroelectric memories, crossbar array memories based on ferroelectric capacitors have a relatively high storage density, can achieve a high-speed read/write of data, and have a good retention and a relatively low power consumption, and are expected to become a substitute for traditional DRAMs. However, with a further research, it has been found that HfO₂-based ferroelectric materials have the characteristics of polycrystalline and multi-domain, and the coercive field distribution of their ferroelectric domains is relatively wide, resulting in significant disturbances to unselected cells when writing and reading the selected cells in the array, which can cause serious bit-flipping problems easily. There is a technology that connects a resistive switching selector in series to a gate of a ferroelectric transistor with a traditional perovskite structure, and utilizes the high resistance of the resistive switching selector at a lower voltage to increase the RC delay during writing, to reduce the gate voltage of the disturbed cell; however, this approach ignores the difference in capacitance values of semiconductor materials at different voltages, at lower voltages, the semiconductor capacitance is smaller, so the RC delay is not high enough, the existing technology cannot effectively reduce the disturbance of unselected cell. Therefore, achieving low-disturbance ferroelectric crossbar array memories have become an urgent problem to be solved.

### SUMMARY OF THE INVENTION

The purpose of the present invention is to propose a high-density ferroelectric memory. The present invention has smaller read/write disturbances, lower bit error rates, and a larger storage window.

The specific technical solution of the present invention is as follows:

A crossbar array ferroelectric capacitor memory, characterized in that, in the memory, multiple memory cells are arranged in an array, and the two sides of the array of the memory cells are connected to substantially orthogonal word lines and bit lines; the memory cell is formed by stacking multiple layers of materials, which are, from top to bottom, a top electrode, a resistive switching dielectric layer, an intermediate metal layer, a ferroelectric dielectric layer, and a bottom electrode, a memory cell connected to both the word/bit lines can complete the read/write operation by applying positive/negative half-select voltages to the word/bit lines simultaneously.

The structure of the memory cell of the present invention adopts a top electrode, a resistive switching dielectric layer, an intermediate metal layer, a ferroelectric dielectric layer, and a bottom electrode, which are electrically equivalent to a ferroelectric capacitor connected in series with a resistive switching selector; when the voltage applied to the memory cell does not exceed a certain limit, the resistive switching selector is in a high resistance state, when the voltage is high enough, the oxygen vacancies in the resistive switching selector or the metal atoms of the electrodes undergo directional migration and form conductive metal filaments that penetrate through the resistive switching dielectric layer, greatly reducing the resistance value of the resistive switching device; the ferroelectric dielectric layer has a spontaneous polarization intensity that can be reversed by an external voltage, enabling non-volatile storage of data.

When positive/negative half-select voltages are applied to a pair of word/bit lines simultaneously, the memory cell connected to both the word/bit lines receives twice the half-select voltage, that is, the full-swing voltage, and this memory cell is the selected memory cell, its resistive switching selector changes to a low resistance state, the RC delay of the entire memory cell is small, and within the application time of the read/write pulse, the voltage of the ferroelectric capacitor can reach the full-swing voltage and undergo ferroelectric spontaneous polarization reversal to complete the read/write operation; other memory cells connected to the corresponding word/bit lines are disturbed memory cells, which are affected by the half-select voltage, the voltage applied to the disturbed memory cells cannot change their resistive switching selector to a low resistance state, thus the RC delay of the disturbed memory cells is relatively large, within the application time of the read/write pulse, the voltage of the ferroelectric capacitor cannot rise to the half-select voltage, reducing the voltage drop of the ferroelectric capacitor and thus reducing the disturbance caused by the half-select voltage to the disturbed memory cell.

The top electrode in the above-mentioned memory cell is a material that is prone to electromigration in the dielectric layer of the resistive switching selector, or a material that is prone to absorb oxygen to generate oxygen vacancies in the dielectric layer, the top electrode is preferably Ag, Ti; in order to provide sufficient stress during annealing to form ferroelectric crystals in the ferroelectric dielectric layer, the intermediate metal layer and the bottom electrode can be selected from the following electrode materials as required: TiN, TaN, Pt, Mo, Ru, W, etc., The resistive switching dielectric layer: dielectric materials based on HfO₂ or TaOₓ and the like which can generate a resistive switching effect; the ferroelectric dielectric layer: traditional ferroelectric materials such as perovskite type ferroelectrics (PZT, BFO, SBT), ferroelectric polymers (P (VDF-TrFE)) etc., or new ferroelectric materials based on HfO₂ that generate ferroelectricity under specific treatments (doping, stress, annealing, etc.) are used. In the above-mentioned crossbar array ferroelectric capacitor memory based on a resistive switching selector, the thickness of the electrode is preferably 10˜100 nm; the thickness of the resistive switching dielectric layer and the ferroelectric dielectric layer is preferably 8˜15 nm.

The present invention further provides an electronic device comprising the aforementioned crossbar array ferroelectric capacitor memory.

The beneficial effects and corresponding principles of the crossbar array ferroelectric capacitor memory based on a resistive switching selector of the present invention:

When accessing a certain memory cell in a ferroelectric capacitor memory with a crossbar array structure, a positive/negative half-select voltage is correspondingly applied respectively to the word/bit lines where the memory cell is located, and the selected memory cell is subjected to a full-swing voltage (twice the half-select voltage), so that the resistive switching selector of the memory cell changes to a low resistance state, and the RC delay of the selected memory cell is greatly reduced, within the read/write pulse time, the ferroelectric voltage is raised to the full-swing voltage, so that ferroelectric polarization reversal occurs, and the read/write operation is completed; but the disturbed memory cells connected to the same word/bit lines are applied with the half-select voltage, so that the resistive switching selector of the memory cell is maintained in a high resistance state, resulting in a larger RC delay of the disturbed memory cells, within the read/write pulse time, the ferroelectric voltage is difficult to rise to the half-select voltage, reducing the disturbance of the half-select voltage on the information stored in the ferroelectric capacitor, lowering the bit error rate of the memory, and improving the storage window, and because the ferroelectric capacitance values in the memory cell is relatively stable at different voltages, the resistive switching selector can effectively reduce the ferroelectric voltage drop in the disturbed memory cells. Compared with traditional crossbar array ferroelectric capacitor memories, the memory of the present invention has smaller read/write disturbances, lower bit error rates, and a larger storage window.

### BRIEF DESCRIPTION OF THE DRAWINGS

FIG. 1 is a schematic diagram of a crossbar array ferroelectric capacitor memory based on a resistive switching selector according to an embodiment of the present invention.

In FIG. 1:

| | |
|---|---|
| 1 - Substrate | 2 - Word Line, WL |
| 3 - Bit Line, BL | 4 - Memory Cell, Storage Cell, SC |

FIG. 2 is a schematic cross-sectional view of a single memory cell according to an embodiment of the present invention.

In FIG. 2:
5—Top Electrode, TE
6—Resistive Switching Dielectric Layer, Upper Dielectric, UD
7—Middle Metal layer, Middle Electrode, ME
8—Ferroelectric Dielectric Layer, Lower Dielectric, LD
9—Bottom Electrode, BE

### DETAILED DESCRIPTION OF THE EMBODIMENTS

The present invention will be further explained through embodiments in conjunction with the accompanying drawings.

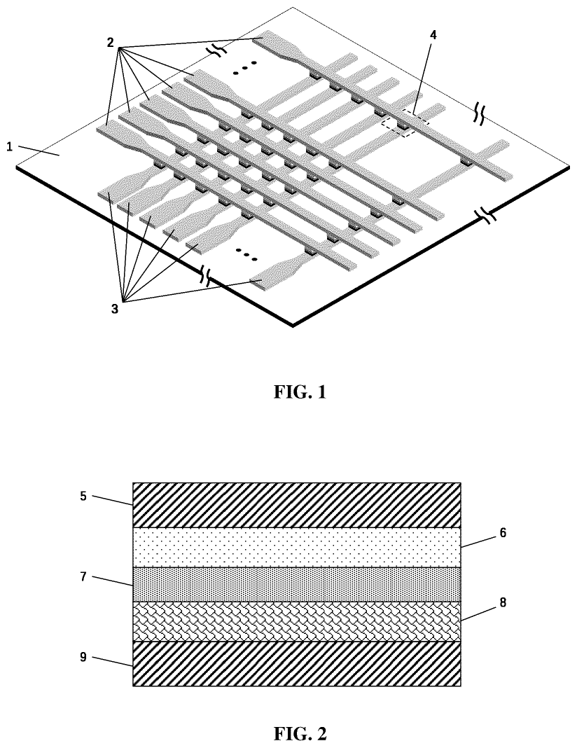

As shown in FIG. 1, this embodiment provides a crossbar array ferroelectric capacitor memory, in the memory, multiple memory cells are arranged in an array, and the two sides of the array of the memory cells are connected to substantially orthogonal word lines and bit lines. As shown in FIG. 2, wherein each memory cell is composed of a top electrode TE, a resistive switching dielectric layer UD, an intermediate metal layer ME, a ferroelectric dielectric layer LD, and a bottom electrode BE from top to bottom, wherein the top electrode is preferably Ag, Ti; the middle metal layer and the bottom electrode use TiN, TaN, Pt, Mo, Ru, W, etc. The resistive switching dielectric layer: a dielectric material based on HfO₂ or TaOₓ and the like that can generate a resistive switching effect; the ferroelectric dielectric layer: traditional ferroelectric materials such as perovskite type ferroelectrics (PZT, BFO, SBT), ferroelectric polymers (P (VDF-TrFE)), or new ferroelectric materials based on HfO₂ that generate ferroelectricity under specific treatments (doping, stress, annealing, etc.) are used. The thickness of the electrode is preferably 10˜100 nm; The thickness of the resistive switching dielectric layer and the ferroelectric dielectric layer is preferably 8˜15 nm. This embodiment also provides a method for preparing the above-mentioned crossbar array ferroelectric capacitor memory based on a resistive switching selector, and the preparation process is as follows:
(1) preparing a bottom electrode on a SiO₂ substrate by physical vapor deposition (PVD) method;
(2) defining a bottom electrode pattern by photolithography, and forming a bottom electrode by wet etching or dry etching methods;
(3) growing a ferroelectric dielectric layer on the surface of the bottom electrode prepared in step (2) by atomic layer deposition (ALD);
(4) defining an intermediate layer metal pattern by photolithography;
(5) growing an intermediate metal layer on a patterned photoresist by PVD method;
(6) stripping and shaping an intermediate metal layer by the way of removing the photoresist;
(7) continuing to grow a resistive switching dielectric layer by ALD;
(8) defining a top electrode pattern by photolithography;
(9) growing a top electrode metal layer on a patterned photoresist by PVD method;
(10) stripping and shaping a top electrode by removing the photoresist;
(11) through rapid thermal annealing (RTA) crystallization under certain conditions, the upper dielectric material is crystallized and the lower dielectric material generates ferroelectricity;
(12) defining a position of the contact hole of the bottom electrode by photolithography;
(13) exposing the bottom electrode by etching for contact.

For example, when accessing a memory cell, a positive half-select voltage V_{dd}/2 is applied correspondingly to the word line where the memory cell is located, a negative half-select voltage—V_{dd}/2 is applied to the corresponding bit line, and other word/bit lines are grounded. At this time, the selected memory cell is subjected to a full-swing voltage Vad, and the resistive switching selector in the memory cell changes to a low resistance state, resulting in a decrease in the RC delay of the memory cell, within the read/write pulse time, the ferroelectric capacitor voltage can rise to the full-swing voltage, enabling writing or reading of information of the ferroelectric capacitor; at the same time, the disturbed memory cell on the same word/bit line is affected by the half-select voltage Vad/2, and its resistive switching selector maintains a high resistance state, resulting in a high RC delay of the memory cell, within the read/write pulse time, the ferroelectric capacitor voltage is difficult to rise to the half-select voltage, and the voltage division of the ferroelectric capacitor is very small, reducing the disturbance of the half-select voltage on the stored information.

The beneficial effects of the present invention are described with this embodiment:

Conventional ferroelectric crossbar array capacitor memory suffers from serious half-select disturbance voltage disturbance problems, and has the disadvantages of high bit error rate and small storage window, the memory cell of the present invention adopts a stacked structure of a top electrode, a resistive switching dielectric layer, an intermediate metal layer, a ferroelectric dielectric layer, and a bottom electrode to reduce the voltage division of unselected cell and reduce its disturbance; and the capacitance value of ferroelectric capacitor is stable, which can effectively reduce the influence of disturbance voltage by RC regulation. In summary, the present invention improves the storage window of the memory and reduces the bit error rate, without increasing additional area overhead.

Finally, it should be noted that the purpose of the disclosed embodiments is to help further understand the present invention, but those skilled in the art can understand that various substitutions and modifications are possible without departing from the spirit and scope of the present invention and the appended claims. Therefore, the present invention should not be limited to the contents disclosed in the embodiments, and the scope of protection claimed by the present invention shall be subject to the scope defined in the claims.

1. A crossbar array ferroelectric capacitor memory, characterized in that, in the memory, multiple memory cells are arranged in an array, and the two sides of the array of the memory cells are connected to substantially orthogonal word lines and bit lines, the memory cell is formed by stacking multiple layers of materials, which are, from top to bottom, a top electrode, a resistive switching dielectric layer, an intermediate metal layer, a ferroelectric dielectric layer, and a bottom electrode, the memory cell connected to both the word/bit lines completes the read/write operation by applying positive/negative half-select voltages to the word/bit lines simultaneously.

2. The crossbar array ferroelectric capacitor memory of claim 1, characterized in that, the resistive switching dielectric layer uses a dielectric material based on HfO₂ or TaOₓ that generates a resistive switching effect.

3. The crossbar array ferroelectric capacitor memory of claim 1, characterized in that, the ferroelectric dielectric layer uses perovskite type ferroelectric materials, ferroelectric polymer materials, or ferroelectric materials based on HfO₂ that generate ferroelectricity after treatment.

4. The crossbar array ferroelectric capacitor memory of claim 1, characterized in that, the top electrode uses Ag or Ti.

5. The crossbar array ferroelectric capacitor memory of claim 1, characterized in that, the intermediate metal layer and the bottom electrode use TiN, TaN, Pt, Mo, Ru, or W.

6. The crossbar array ferroelectric capacitor memory of claim 1, characterized in that, the thickness of the top electrode, the bottom electrode, or the intermediate metal layer is in the range of 10˜100 nm.

7. The crossbar array ferroelectric capacitor memory of claim 1, characterized in that, the thickness of the resistive switching dielectric layer or the ferroelectric dielectric layer is in the range of 8˜15 nm.

8. A method for preparing a crossbar array ferroelectric capacitor memory, comprising the steps of:
1) preparing a bottom electrode material on a substrate by physical vapor deposition;
2) defining a bottom electrode pattern by photolithography, and forming a bottom electrode by wet etching or dry etching methods;
3) growing a ferroelectric dielectric material on the surface of the bottom electrode by atomic layer deposition;
4) defining an intermediate layer metal pattern by photolithography;
5) growing an intermediate metal layer on a patterned photoresist by physical vapor deposition method;
6) stripping and shaping the intermediate metal layer by removing the photoresist;
7) continuing to grow a resistive switching dielectric material by atomic layer deposition method;
8) defining a top electrode pattern by photolithography;
9) growing a top electrode metal layer on a patterned photoresist by physical vapor deposition method;
10) stripping and shaping the top electrode by removing the photoresist;
11) through rapid thermal annealing crystallization, the resistive dielectric material is crystallized, and the ferroelectric dielectric material generates ferroelectricity;
12) defining a position of contact hole of the bottom electrode by photolithography;
13) exposing the bottom electrode by etching for contact.

9. An electronic device characterized by comprising the crossbar array ferroelectric capacitor memory as described in claim 1.

10. An electronic device characterized by comprising the crossbar array ferroelectric capacitor memory as described in claim 2.

11. An electronic device characterized by comprising the crossbar array ferroelectric capacitor memory as described in claim 3.

12. An electronic device characterized by comprising the crossbar array ferroelectric capacitor memory as described in claim 4.

13. An electronic device characterized by comprising the crossbar array ferroelectric capacitor memory as described in claim 5.

14. An electronic device characterized by comprising the crossbar array ferroelectric capacitor memory as described in claim 6.

15. An electronic device characterized by comprising the crossbar array ferroelectric capacitor memory as described in claim 7.
